(19) United States
(12) Patent Application Publication
(10) Pub. No.: US 2026/0313939 A1
(43) Pub. Date: Oct. 8, 2026

(54) Method for Forming a Memory Structure for a 3D NAND Flash Memory

(71) Applicant: IMEC VZW, Leuven (BE)

(72) Inventors: Sana Rachidi, Leuven (BE); Maarten Rosmeulen, De Pinte (BE); Silvia Armini, Heverlee (BE); Geert Van den Bosch, Kessel-Lo (BE)

(21) Appl. No.: 19/639,909

(22) Filed: Apr. 6, 2026

(30) Foreign Application Priority Data
Apr. 7, 2025 (EP) 25168748.9

(51) Int. Cl. H10D 30/01; H10B 43/27; H10B 43/35; H10D 30/69

(52) U.S. Cl. CPC H10D 30/0413; H10B 43/27; H10B 43/35; H10D 30/693

(57) ABSTRACT

A method for forming a memory structure for a three-dimensional NOT-AND flash memory is disclose. A method may include forming a layer stack an alternating sequence of gate layers and inter-gate spacer layers of over a substrate. The method may also include forming recessed areas in a sidewall surrounding a memory hole in the layer stack and forming an initial charge trap layer in each recessed area. The method may further include depositing a tunneling oxide layer in the memory hole and depositing a channel layer on the tunneling oxide layer. Additionally, the method may include forming an access trench in the layer stack and forming gate cavities in the layer stack. In addition, the method may include oxidizing a portion of the initial charge trap layer in each gate cavity such that the oxidized portion forms a blocking oxide layer and forming gate layers.

### CROSS-REFERENCE TO RELATED APPLICATIONS

The present application is a non-provisional patent application claiming priority to European Patent EP 25168748.9, filed Apr. 7, 2025, the contents of which are hereby incorporated by reference.

### FIELD OF THE DISCLOSURE

The present disclosure relates to a method for forming a memory structure for a three dimensional (3D) NOT-AND (NAND) flash memory

### BACKGROUND

The bit density in the 3D NAND flash memory road map may increase. Thus far, the increase may be facilitated by increasing the number of memory cells stacked along the vertical dimension. However, such a route may become increasingly difficult and costly. Hence, there may be interest in techniques for scaling the cells along the vertical dimension. Vertical scaling (“z-pitch scaling”) may be facilitated by reducing the thickness of the layers in the layer stack, e.g. the word line (gate) layers and oxide inter-gate spacer layers.

3D NAND technology may be based on the so-called charge trap cell utilizing a charge trap layer (e.g. of SiN) as a storage layer. The charge trap layer may be separated from the gate layers by a blocking oxide layer. The charge trap layer and the blocking oxide layer may be deposited as continuous layers along the sidewall of the memory hole in the layer stack. Z-scaling may result in a reduced inter-cell separation, which in turn may reduce the retention performance of the continuous charge trap layer. There may hence be a need for scalable techniques that facilitate forming of an interrupted charge trap layer such that each memory cell may be provided with a separate charge trap layer.

### SUMMARY

An approach for forming an interrupted charge trap layer may be to, in sequence: recess the gate layers of the memory stack relative to the inter-gate spacer layers from the memory hole by an isotropic etch, deposit a continuous blocking oxide layer along the sidewall of the memory hole and in the recesses, cut the continuous blocking oxide layer by an isotropic etch back to form a discrete blocking oxide layer in each recess, deposit a continuous charge trap layer along the sidewall of the memory hole and in the recesses, and cut the continuous charge trap layer by an isotropic etch back to form a discrete charge trap layer on the blocking oxide layer in each recess. However, this way of processing may involve two controlled isotropic etch back processes to uniformly cut the blocking oxide and charge trap layers. Such process control may be challenging to obtain at the scaled z-pitches that may be considered in the future 3D NAND roadmap.

In some embodiments, methods may facilitate reliable forming of interrupted/cut blocking oxide and charge trap layers also at aggressive z-pitch scaling. In particular, this may be facilitated while reducing use of controlled isotropic etch back processes for cutting the continuous blocking and charge trap layers.

Hence, according to an aspect of the present disclosure, there is provided a method for forming a memory structure for a 3D NAND flash memory, the method includes forming a layer stack over a substrate. The layer stack includes an alternating sequence of gate layers and inter-gate spacer layers. The method also includes forming recessed areas in a sidewall surrounding a memory hole in the layer stack by laterally etching back the gate layers relative to the inter-gate spacer layers from the memory hole. The method further includes forming an initial charge trap layer in each recessed area. Moreover, the method includes depositing a tunneling oxide layer in the memory hole. Additionally, the method includes depositing a channel layer on the tunneling oxide layer and forming an access trench in the layer stack. Still further, the method includes forming gate cavities in the layer stack by laterally etching back the gate layers from the access trench in a direction towards the memory hole. The gate cavities expose the initial charge trap layers. Yet further, the method includes oxidizing a portion of the initial charge trap layer in each gate cavity such that the oxidized portion forms a blocking oxide layer and a non-oxidized portion of the initial charge trap layer remains to form a final charge trap layer between the blocking oxide and the memory hole. In addition, the method includes, subsequent to forming the blocking oxide layer and the final charge trap layers, forming gate layers in the gate cavities by depositing gate material in the gate cavities via the access trench.

The methods described herein facilitate forming of a memory structure that includes vertically separated lateral memory stacks, each including a respective discrete blocking oxide layer and a respective discrete charge trap layer for each gate layer or for each memory cell.

Rather than depositing a continuous blocking oxide layer in the recessed areas and subsequently “cutting” the blocking oxide layer into a number of discrete portions by etching, the method may form the discrete blocking oxide layers by oxidizing a portion of the initial charge trap layers. The initial charge trap layers may be accessed via a radially outer access trench and gate cavities formed between the inter-gate spacer layers by removing the “sacrificial” gate layers. Hence, discrete blocking oxide layers may be formed at each gate level without a separate deposition and etching of a continuous blocking oxide layer.

This may facilitate reducing process variability, since the thickness (in the lateral direction) of the blocking oxide layers may be precisely controlled via the extent/depth of the oxidation of the initial charge trap layers. This may be easier than attempting precise thickness control by deposition and etch back of blocking oxide material in recessed areas from the memory hole.

The reduced process variability in turn may facilitate forming of discrete charge trap layers. The inter-gate spacer layers may be an oxide (e.g., silicon oxide). Therefore, area-selective deposition (ASD) of charge trap material on previously deposited blocking oxide layers in the recessed areas may be challenging without any appreciable concurrent deposition on the inter-gate spacer layers. However, as the charge trap layers may be formed prior to forming the blocking oxide layers, the gate layers may be accessed from the memory hole. The gate layers may provide a material contrast to inter-gate spacer layers, e.g., by being formed of a non-oxide material such as a nitride, e.g., silicon nitride, amorphous silicon (a-Si), or polysilicon. Thus, the gate layers may facilitate deposition of charge trap material with a sufficient area selectivity to facilitate ASD of charge trap material in the recessed areas. Embodiments for ASD of discrete charge trap layers in the recessed areas are described below.

The reduced process variability conferred by the oxidation-based approach for forming the blocking oxide layers may facilitate forming of discrete charge trap layers in the recessed areas also using non-ASD approaches.

In view of the above, regardless of whether the charge trap layers may be formed using ASD or non-ASD approaches, the method may limit the number of deposition and etch back processes used to form discrete blocking oxide layers.

The methods described herein may facilitate the above discussed advantages with little impact on the overall process complexity. The access trench and gate cavities may subsequently be used to provide the functional gate material, e.g., a replacement metal gate (RMG) layer or stack at each gate level.

In some embodiments, methods described herein further include prior to forming the initial charge trap layers, forming an etch stop layer on the etched-back gate layers in the recessed areas and subsequently depositing the initial charge trap layer in each recessed area, on the etch stop layer.

The provision of an etch stop layer may further contribute to improved process control, since the lateral etch back of the gate layers from the access trench thus may be reliably stopped on the etch stop layer. This may contribute to more uniform gate cavities, also in scenarios where the gate layers and the initial charge trap layers are formed of materials with little to no etch contrast (such as where both may be formed of silicon nitride). In any case, the etch stop layer may serve to mask the initial charge trap layers from the etching chemistries used to etch the gate layers.

The method may further include, prior to oxidizing the portion of the initial charge trap layer in each gate cavity, opening the etch stop layer to expose the initial charge trap layer. The initial charge trap layer may thus be exposed to the oxidizing ambient or chemistries of the subsequent oxidation process.

In some embodiments, the etch stop layer may be deposited in each recessed area by a (first) area-selective deposition process.

Hence, etch stop layers may be deposited by ASD of etch stop material in each recessed area. During the ASD of etch stop material, the gate layers may define deposition-promoting (seeding) areas while the inter-gate spacer layers may define deposition-inhibiting (non-growth) areas (e.g., after being subjected to surface passivation), which may thereby contribute to a selective deposition of the blocking oxide material in the recessed areas.

In some embodiments, the initial charge trap layer may be deposited on the etch stop layer in each recessed area by a (second) area-selective deposition process.

Thus, rather than depositing a continuous charge trap layer and subsequently “cutting” the charge trap layer into a number of discrete portions by etching, discrete charge trap layers may be “directly” deposited in the recessed areas by ASD. The (discrete) etch stop layers in the recessed areas may define seeding (deposition-promoting) areas (“growth areas”) while the inter-gate spacer layers may define deposition-inhibiting (non-growth) areas (e.g., after being subjected to surface passivation), thereby may contribute to a selective deposition of the charge trap material of the charge trap layers. Deposition of the charge trap material in areas vertically between the gate layers may hence be avoided (e.g., on end surfaces of the inter-gate spacer layers facing the memory hole), which may thus obviate the need for cutting a continuous layer of charge trap material by etching. By doing so, the lateral thickness of the charge trap layers (e.g., the thickness dimension as seen along the lateral direction) may be controlled by maintaining the growth conditions of the selective deposition until a target thickness has been achieved.

In some embodiments, a portion of the initial charge trap layers may be oxidized by a thermal oxidation process. The blocking oxide layers may thus be formed using a simple, reliable and cost-effective process, which further may be relatively benign to non-targeted layers, such as the inter-gate spacer layers. A thermal oxidation process may also facilitate a reliable oxidation in high-aspect ratio structures.

In some embodiments, the portion of the initial charge trap layer may be oxidized by a plasma oxidation process.

In some embodiments, the access trench may be formed after depositing the tunneling oxide layer and the channel layer. This may facilitate a rational overall process flow that may reduce separate covering and reveal of the charge trap layers from the memory hole prior to and after, respectively, forming the blocking oxide layer.

In some embodiments, methods described herein may include filling the memory hole with a plug material prior to forming the access trench. The charge trap layers and, if present the tunneling oxide and channel layers, may thus be covered from the side of the memory hole prior to forming the access trench.

In some embodiments, the plug material may include an oxide. This may be advantageous in embodiments where the plug material is deposited after forming the tunneling oxide and channel layers. The oxide may remain as an insulating filler in the memory hole of the finished memory structure.

In some embodiments, the methods described herein may include forming of an etch stop layer. The etch stop layer may include a metal oxide or a metal nitride. Such etch stop materials (e.g., aluminum oxide, hafnium oxide, titanium oxide or titanium nitride) may facilitate process control as they may provide sufficient etch contrast with respect to typical sacrificial gate layer materials and charge trap materials. Further, they may define efficient deposition-promoting surfaces with respect to ASD of the charge trap material, notably relative to non-metal oxide or non-metal nitride (typically silicon oxide) inter-gate spacer layers. Further, metal oxides or metal nitrides may be reliably deposited by ASD on typical sacrificial gate layer materials.

In some embodiments, the etch stop layer may be formed with a (lateral) thickness of 2 nanometers (nm) or less. Since the etch stop layer may only function as an etch stop layer and, optionally, seeding layer for ASD of charge trap material, it may be formed as a relatively thin layer. The etch stop layer need hence not unnecessarily encroach upon the depth of the recessed areas available for the initial charge trap layers.

In some embodiments, the initial charge trap layers may be a silicon-comprising layer, such as silicon nitride layers. Silicon-comprising layers may be suitable for charge trap layers.

Silicon nitride may be an efficient and rational realization of charge trap-based memory cells. Further, silicon nitride may be suitable for ASD onto conformal metal oxides or metal nitrides, without causing any appreciable co-deposition onto silicon oxide. Silicon-comprising layers (such as silicon nitride) may also be oxidized (e.g., in a thermal process) to form a high-quality blocking oxide.

### BRIEF DESCRIPTION OF THE FIGURES

The above, as well as additional, features will be better understood through the following illustrative and non-limiting detailed description of example embodiments, with reference to the appended drawings.

FIG. 1a shows a schematic cross-sectional view of a structure for forming a memory structure, according to example embodiments.

FIG. 1b shows a top-down view of a structure for forming a memory structure, according to example embodiments.

FIG. 2 shows the structure after forming recessed areas, according to example embodiments.

FIG. 3 shows the structure after forming etch stop layers in the recessed areas, according to example embodiments.

FIG. 4 shows the structure after forming initial charge trap layers in the recessed areas, according to example embodiments.

FIG. 5 shows the structure after forming tunneling oxide layers and channel layers and plugging the memory hole, according to example embodiments.

FIG. 6 shows the structure after removing an access trench in the layer stack, according to example embodiments.

FIG. 7 shows the structure after forming gate cavities, according to example embodiments.

FIG. 8 shows the structure after opening the etch stop layers in the gate cavities, according to example embodiments.

FIG. 9 shows the structure after partially oxidizing the etch stop layers to form blocking oxide layers in each gate cavity, according to example embodiments.

FIG. 10 shows the structure after filling the gate cavities with gate material, according to example embodiments.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

Example embodiments may include a method for forming a memory structure for a 3D NAND flash memory, such as a 3D-Gate-All-Around-NAND (3D GAA NAND).

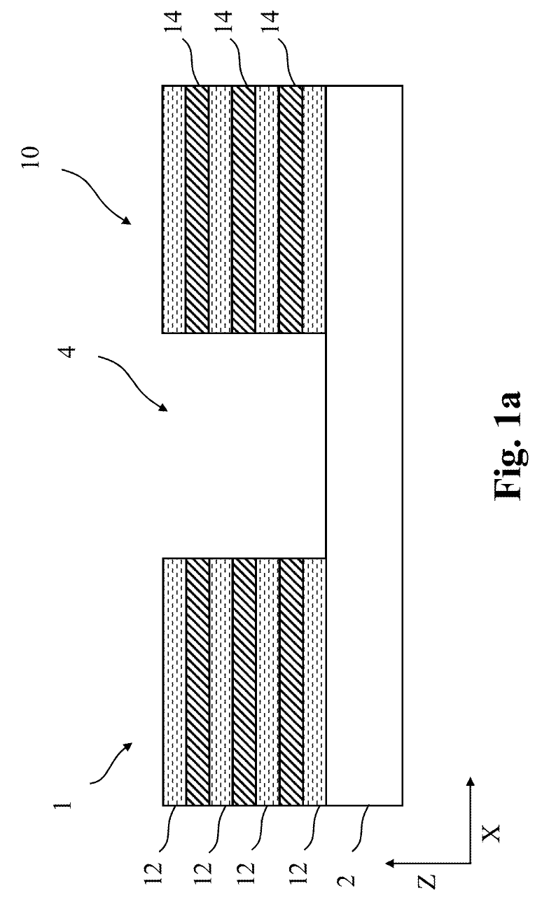

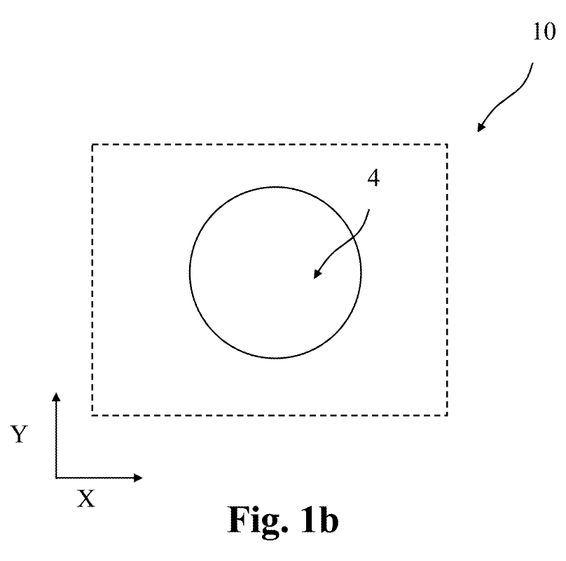

The drawings are only schematic and the relative dimensions of some structures and layers may be exaggerated and not drawn to scale. Rather the dimensions may be adapted for illustrational clarity and to facilitate understanding. When present in the figures, the indicated axes X, Y and Z consistently refer to a first horizontal or lateral direction, a second horizontal or lateral direction, and a vertical direction, respectively. As used herein, the terms “horizontal” and “lateral” refer to directions parallel to (a main surface of) a supporting substrate of the memory structure. A lateral/horizontal direction may also be understood as a direction parallel to an in-plane direction of the gate and inter-gate spacer layers. The term “vertical” refers to a direction parallel to a normal direction to (the main surface of) the substrate, e.g. transverse to the substrate. Reference is herein also made to a “radial” direction. This term is to be understood as a radial direction with respect to a given memory hole (e.g., memory hole 4 in FIG. 1a), parallel to the horizontal XY-plane. The terms “radially inward” and “radially outward” accordingly refers to radially inward and outward directions, respectively, with respect to a given memory hole. Related terms, such as “radially inner,” “radially,” and “radially outer” may correspondingly be used to indicate a relative radial location or distance of a feature or element, relative to the given memory hole.

FIG. 1a shows a schematic cross-sectional view of a structure 1 for forming a memory structure, according to example embodiments.

FIG. 1b shows a top-down view of a structure 1 for forming a memory structure, according to example embodiments.

FIGS. 1a and 1b may depict structure 1 at an initial stage of the method. Structure 1 may include layer stack 10 representing a precursor or starting structure for the memory structure, to be subjected to the processing steps of the method disclosed in the following.

Layer stack 10 may be formed over substrate 2 and may include an alternating sequence of gate layers 14 and inter-gate spacer layers 12. Inter-gate spacer layers 12 and gate layers 14 may be stacked on top of each other along the vertical direction Z.

Substrate 2 may be a conventional substrate, suitable for semiconductor processing and for supporting a memory structure for a 3D NAND flash memory. Substrate 2 may for instance be a Si substrate, a Ge substrate, or a SiGe substrate. Other examples may include a silicon-on-insulator (SOI) substrate, a GeOI substrate or a SiGeOI substrate.

Gate layers 14 may include silicon-comprising layers, such as SiN layers, a-Si layers, a-Si layers, or polysilicon layers. Gate layers 14 may be sacrificial gate layers intended to be replaced by an RMG stack in subsequent process steps.

Inter-gate spacer layers 12 may be oxide-comprising layers, such as silicon oxide (e.g., SiO₂) layers or another suitable inter-layer dielectric (e.g., of low-k). Inter-gate spacer layers 12 may be arranged in layer stack 10 to provide vertical separation between the memory cells / word lines of the memory device which may be formed.

Layer stack 10 may be formed by interchangeably depositing layers of gate material (e.g. nitride) and inter-gate spacer material (e.g. oxide) using deposition processes, such as chemical vapor deposition (CVD), physical vapor deposition (PVD), or atomic layer deposition (ALD).

Inter-gate spacer layers 12 and gate layers 14 may be formed in numbers in accordance with the intended number of stacked memory cells of the memory device. The number of inter-gate spacer layer 12 and gate layers 14 of layer stack 10 illustrated in FIGS. 1a-10 is a non-limiting example and that the methods disclosed herein are compatible with stacks of any number of memory cells, such as 64, 128, 256 or greater.

Inter-gate spacer layers 12 and gate layers 14 may each be formed with a respective layer thickness in a range of 5-25 nm. A z-pitch of layer stack 10 (e.g. the combined thickness of one inter-gate spacer layer of inter-gate spacer layers 12 and one gate layer of gate layers 14) may be in a range from about 45 nm to 15 nm or less.

While omitted for ease of illustration, layer stack 10 may be capped by a capping layer, for instance a semiconductor layer (e.g., silicon), deposited on top of the top-most inter-gate spacer layer of inter-gate spacer layers 12. A capping layer may serve to protect the top-most inter-gate spacer layer of inter-gate spacer layers 12 during the following processing.

After depositing inter-gate spacer layers 12 and gate layers 14 (and optionally a capping layer) of layer stack 10, memory hole 4 may be patterned in layer stack 10, e.g. by a lithography and etching process. While FIGS. 1a and 1b show a portion of layer stack 10 surrounding a single memory hole 4, it is noted that a corresponding memory hole 4 may be patterned at each location where a respective vertical string of memory cells may be desired. Memory hole 4 may be formed to extend through each one of inter-gate spacer layers 12 and gate layers 14 of layer stack 10. Memory hole 4 may be formed with a circular cross-sectional shape (footprint), such that memory hole 4 may be formed with a substantially circular cylindrical shape. However, memory hole 4 may also be formed with other cross-sectional shapes, such as an oval or polygonal shape.

While not shown in FIG. 1a, layer stack 10 may include, underneath inter-gate spacer layers 12 and gate layers 14, a sub-stack of a select layer and a source layer for forming a select plate and a source plate, respectively, of the memory device. The select and source layers may hence form a bottom sub-stack of layer stack 10. The select and source layers may be formed by using doped semiconductor layers (e.g. polysilicon) and be separated by layers of interlayer dielectric.

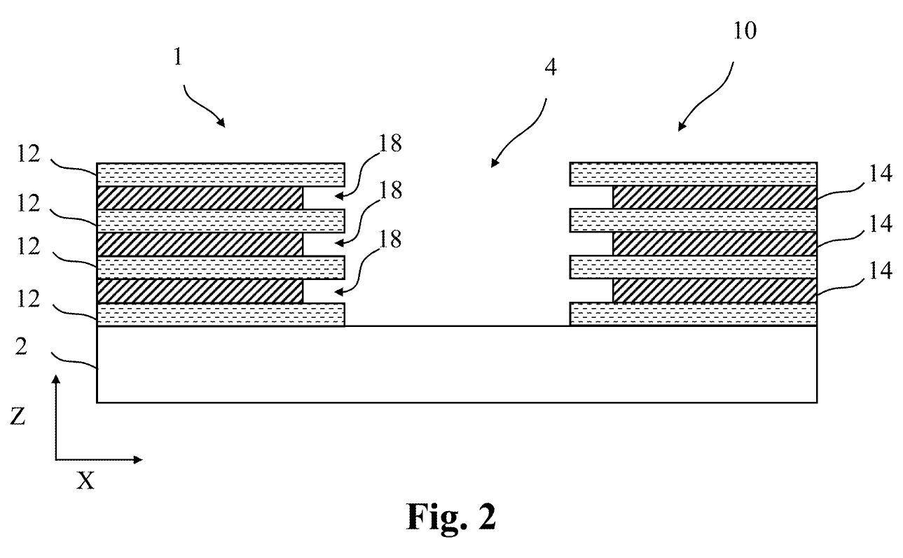

FIG. 2 shows the structure 1 after forming recessed areas, according to example embodiments. As shown in FIG. 2, recessed areas 18 may be formed in a sidewall of layer stack 10 surrounding memory hole 4 by laterally etching back (e.g., in a radially outward direction, along the X-axis) gate layers 14 relative to inter-gate spacer layers 12 from memory hole 4. Thereby, each recessed area of recessed areas 18 may be formed between a pair of inter-gate spacer layers of inter-gate spacer layers 12. Due to the circumferential extension of the sidewall about memory hole 4, recessed areas 18 may extend circumferentially about memory hole 4. If memory hole 4 is circular, recessed areas 18 may be annular.

Gate layers 14 may be etched back using an etching process adapted to etch gate layers 14 selectively to inter-gate spacer layers 12. That is, the etching process may etch (e.g. remove) the material (e.g. the silicon nitride, a-Si or polysilicon) of gate layers 14 selectively to the material (e.g. the oxide material) of gate layers 14, such that gate layers 14 may be laterally etched back without causing any substantial etch-back of inter-gate spacer layers 12. The etching process may be applied to the sidewall of layer stack 10 via memory hole 4. The etching process may be an isotropic etching process. However, any suitably selective etching process, wet or dry, that may provide a sufficient lateral etching component for gate layers 14 may be used.

Recessed areas 18 may be formed with a lateral/radial depth (along the X-axis) meeting or exceeding an intended lateral thickness of the lateral memory stacks, e.g., a combined lateral thickness of the blocking oxide and charge trap layers at each gate-level. The lateral depth of recessed areas 18 may be determined by the lateral depth (radial extent) of the lateral etch back. The lateral depth of recessed areas 18 may be in a range of 6-20 nm. The depth of recessed areas 18 may be controlled by timing the lateral etch back.

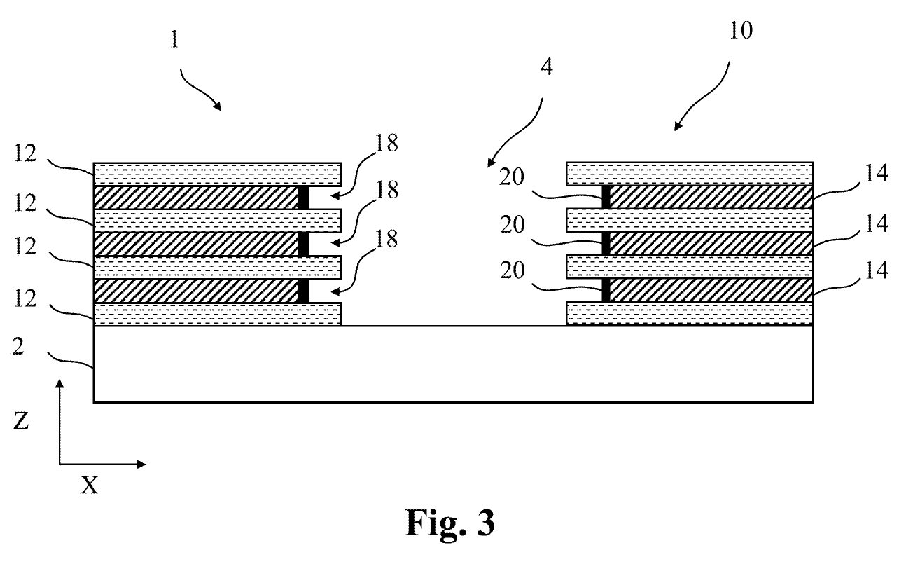

FIG. 3 shows the structure 1 after forming etch stop layers in the recessed areas, according to example embodiments. As shown in FIG. 3, etch stop layers 20 may be deposited on etched-back gate layers 14 in recessed areas 18. Etch stop layers 20 may be discrete layers, each formed in a respective recessed area of recessed areas 18, e.g., on a respective gate layer of gate layers 14.

Etch stop layers 20 may act as etch stop layers during a subsequent step of gate cavity formation. Etch stop layers 20 may be seeding layers for ASD of charge trap material. Etch stop layers 20 may be removed prior to forming blocking oxide layers. Accordingly, etch stop layers 20 may be temporary process layers that may not have any function or be present in the final memory structure. Hence, etch stop layers 20 may be formed as relatively thin layers and may be no thicker than needed.

Since recessed areas 18 may accommodate initial charge trap layers 21 of some minimum target thickness, each etch stop layer of etch stop layers 20 may be deposited to partially fill an associated recessed area of recessed areas 18. Hence, subsequent to forming etch stop layers 20, the sidewall of memory hole 4 may define a recessed / profiled sidewall. Etch stop layers 20 may be formed with a thickness that may be smaller than a lateral depth (along the X axis) of recessed areas 18. The thickness an etch stop layer of etch stop layers 20 may refers to the lateral thickness, its thickness along the X axis, e.g., parallel to the in-plane direction of gate layers 14. For instance, etch stop layers 20 may be formed with a thickness of about 2 nm or less, such as about 1 nm. A thickness in this range may be compatible with the above-mentioned ranges of depth of recessed areas 18 and thickness ranges of initial charge trap layers 21.

Etch stop layers 20 may include a metal oxide or a metal nitride, such as AlOₓ, HfOₓ, TiN, TiO₂, or some other material (e.g., high-k oxide or nitride) suitable to be used as a etch stop material. These materials may further facilitate ASD of charge trap material.

Etch stop layers 20 may be deposited on etched-back gate layer 14 in each recessed area of recessed areas 18 by an ASD process (a first ASD process). Thus, etch stop material for forming etch stop layers 20 may be deposited selectively in recessed areas 18. The deposition may be continued until discrete portions of etch stop material of a target thickness have been deposited in each recessed area of recessed areas 18, each portion may define a respective discrete etch stop layer of etch stop layers 20. During the ASD, the etched-back end surfaces of gate layers 14 facing memory hole 4 may define deposition-promoting (seeding) areas for the etch stop material while inter-gate spacer layers 12 may define deposition-inhibiting (non-growth) areas. Etch stop material may be deposited using a deposition process (e.g. an ALD or CVD process), which may facilitate ASD of the etch stop material in recessed areas 18.

The material of gate layers 14 (e.g., silicon nitride, a-Si or polysilicon) may provide growth-promoting surfaces relative to the inter-gate spacer layers (e.g., silicon oxide) to facilitate ASD of the etch stop material (e.g. metal oxides or nitrides). To facilitate ASD of etch stop layers 20, layer stack 10 may be subjected to a treatment process prior to depositing the etch stop material, which may define growth areas in recessed areas 18 (e.g., on the end surfaces of etched-back gate layers 14) and non-growth areas outside recessed areas 18. The treatment process may be adapted to functionalize the surface portions/end surfaces of etched-back gate layers 14 in recessed areas 18 with respect to the ASD of the etch stop material. The treatment process may additionally or alternatively be adapted to passivate exposed surface portions of inter-gate spacer layers 12 with respect to the ASD of the blocking oxide material. Etch stop material may be deposited selectively in the growth areas in recessed areas 18. For instance, the functionalization may include depositing a deposition-promoting layer on the end surfaces of etched-back gate layers 14 in recessed areas 18. Layer stack 10 may be subjected to a treatment process adapted to passivate expose surface portions of inter-gate spacer layers 12 with respect to the ASD of the etch stop material. For instance, some deposition processes may involve deposition on hydrogen terminated surfaces (e.g. the deposition process deposits material preferentially on hydrogen terminated surfaces). A treatment process may hence be adapted to increase an occurrence of hydrogen terminated bonds on gate layers 14 (thus may promote deposition thereon) and/or reduce an occurrence of hydrogen terminated bonds on inter-gate spacer layers 12 (thus may inhibit deposition thereon). As a further example, silicon oxide (SiO₂) inter-gate spacer layers 12 may be passivated selectively to silicon nitride/a-Si/polysilicon gate layers 14 using siloxanes, aminosilanes, trichlorosilanes, small molecule inhibitors (SMIs) (e.g., dimethylamino-trimethylsilane (DMA-TMS), trimethyltrimethoxysilane, trimethoxytrichlorosilane) or self-assembled monolayers (SAMs) (e.g., alkylsilanes), to facilitate ASD of the etch stop material on the end surfaces of gate layers 14.

A non-selective deposition of etch stop material may be used to form etch stop layers 20. For instance, etch stop material may be deposited by a conformal and non-selective deposition process. Portions of the etch stop material deposited outside recessed areas 18 may subsequently be removed by an anisotropic etching process biased in a direction (e.g., substantially top-down, in the -Z direction) such that the etch stop material deposited inside recessed areas 18 may be shadowed from the etching chemistries by the overhang provided by inter-gate spacer layers 12, at least on the etched-back end surfaces of gate layers 14, which may define the surface portions farthest from memory hole 4. As etch stop layers 20 may be formed as relatively thin layers (e.g., about 2 nm or less), portions of etch stop material that may remain on surface portions of inter-gate spacer layers 12 within recessed areas 18 may have a relatively minor impact on the available space for initial charge trap layers 21. Additionally, a relatively brief etch step may suffice to remove charge trap material deposited outside recessed areas 18. In some embodiments, the non-selective deposition approach described below with respect to the charge trap material may be applied in a corresponding manner to facilitate a non-selective deposition of the etch stop material. In this case, the etch back of etch stop material may proceed until the etch stop material remains substantially only on the etched-back end surfaces of gate layers 14, which may define the surface portions farthest from memory hole 4.

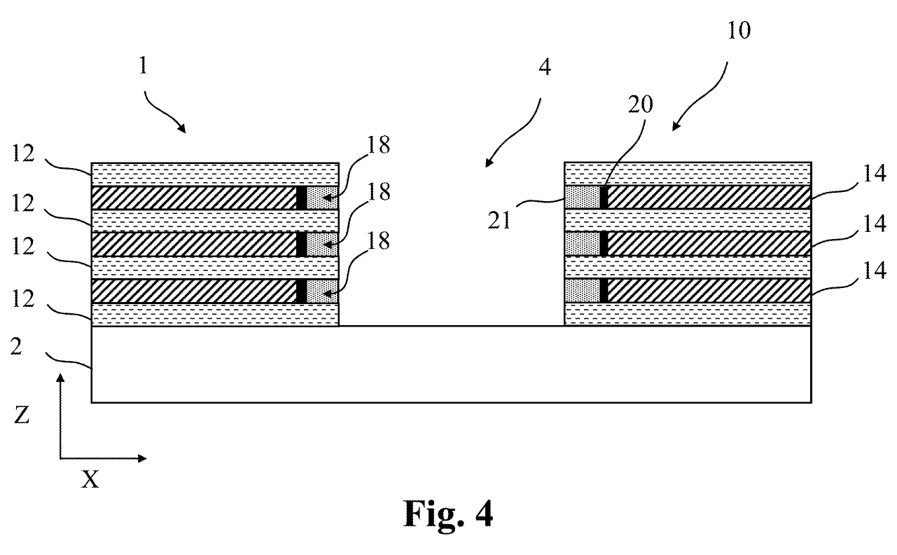

FIG. 4 shows the structure 1 after forming initial charge trap layers 21 in the recessed areas, according to example embodiments. As shown in FIG. 4, initial charge trap layers 21 may be formed in each recessed area of recessed areas 18. Initial charge trap layers 21 may be discrete layers, each formed in a respective recessed area of recessed areas 18, on an etch stop layer of etch stop layers 20.

Initial charge trap layers 21 may be formed by an ASD process (a second ASD process) using a respective etch stop layer of etch stop layers 20 as a seeding layer. Thus, charge trap material may be deposited selectively in recessed areas 18, seeding from (nucleating on) the respective etch stop layer of etch stop layers 20.

The deposition of the charge trap material may be continued until discrete portions of charge trap material of a target thickness have been deposited in recessed areas 18, each portion may define a respective discrete initial charge trap layer 21. During the ASD, inter-gate spacer layers 12 may define deposition-inhibiting (non-growth) areas while etch stop layers 20 may define deposition-promoting (seeding) areas for the charge trap material.

The charge trap material may include silicon nitride (SiN), such as Si₃N₄). Silicon nitride may represent an efficient and rational realization of charge trap memory cells. Silicon nitride may be deposited by ASD onto any of the above-mentioned examples of etch stop materials (metal oxides or metal nitrides, such as AlOₓ, HfOₓ, TiN, TiO₂). In some embodiments, the charge trap material may include silicon. The initial charge trap layers 21 may be silicon-comprising layers. Initial charge trap layers 21 may be composite layer structures. For example, initial charge trap layers 21 may include first and second sequentially deposited layers (sub-layers). The first sub-layer may include and the second sub-layer may include a metal layer, such as TiN or Ru. The first sub-layer may be the portion of initial charge trap layers 21 exposed from gate cavities 22. Thus, the first layer of each initial charge trap layer of initial charge trap layers 21 may include silicon, such that blocking oxide layers 24 may be formed by oxidation of initial charge trap layers 21. ASD may be used also for other choices of charge trap material, if they may be deposited in an area-selective fashion on etch stop layers 20 in recessed areas 18 and may be oxidized to form blocking oxide layers 24. The charge trap material may be deposited using any suitable deposition process, conformal or non-conformal, such as an ALD or CVD process.

To facilitate the ASD of the charge trap material, layer stack 10 may be subjected to a treatment process prior to depositing the charge trap material, to define growth areas in recessed areas 18 (e.g., on etch stop layers 20) and non-growth areas outside recessed areas 18. The treatment process may be adapted to (further) functionalize etch stop layers 20 with respect to the ASD of the charge trap material. The treatment process may additionally or alternatively be adapted to passivate exposed surface portions of inter-gate spacer layers 12 with respect to the ASD of the charge trap material. Thereafter, the charge trap material may be deposited selectively on the growth areas in recessed areas 18. The examples of functionalization and passivation discussed above with reference to ASD of blocking oxide material apply to ASD of charge trap material. For example, a SiO₂ surface may be passivated by dimethylamino-trimethylsilane (DMA-TMS) inhibition selectively to either TiO₂ or TiN.

A non-selective deposition of charge trap material may be used to form initial charge trap layers 21. For instance, charge trap material may be deposited as a continuous layer by a conformal deposition process to completely fill (e.g., by pinch-off) recessed areas 18. A local lateral thickness (along the X direction) of the charge trap material deposited in recessed areas 18 may exceed a local thickness of the charge trap material deposited outside recessed areas 18. The charge trap material may subsequently be etched back (e.g., isotropically) such that the portions of the charge trap material deposited outside recessed areas 18 may be removed and such that portions of the charge trap material filling recessed areas 18 remain that may define discrete initial charge trap layers 21 therein.

Blocking oxide layers 24 may be formed. There may be no preceding deposition and etch-back of blocking oxide. There may be little variability among recessed areas 18 (e.g., in terms of depth, height and profile of the interior spaces of recessed areas 18). More uniform recessed areas may facilitate control of both deposition thickness and/or etch back of a continuous charge trap layer.

The initial charge trap layers 21 may each be formed with a lateral thickness (along the X axis) in a range of about 6-20 nm (e.g., 6-20 nm minus the thickness of etch stop layers 20). The initial charge trap layers 21 may completely fill the remaining interior spaces of recessed areas 18 following the forming of etch stop layers 20. End surfaces of the discrete initial charge trap layers 21 facing memory hole 4 may become flush with the end surfaces of inter-gate space layers 12 facing memory hole 4. A sidewall of memory hole 4 may be restored to a straight profile, or at least with a reduced topography compared prior to forming initial charge trap layers 21.

In some embodiments, each recessed area of recessed areas 18 may be provided with (e.g., “re-filled” and/or “re-grown” with) a corresponding etch stop layer of etch stop layers 20 and an initial charge trap layer of initial charge trap layers 21.

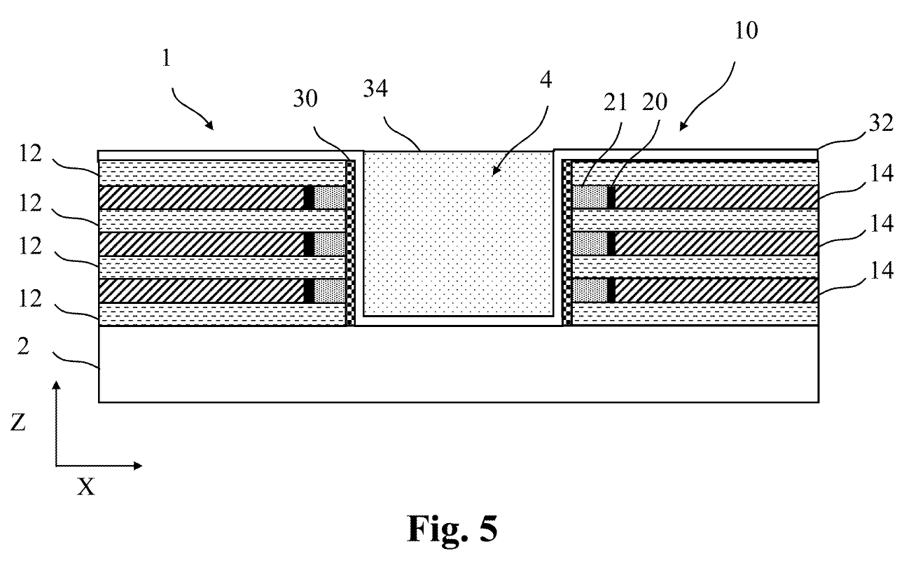

FIG. 5 shows the structure 1 after forming tunneling oxide layer 30 and channel layer 32 and plugging memory hole 4, according to example embodiments.

As shown in FIG. 5, tunneling oxide layer 30 and channel layer 32 may be formed in memory hole 4, such as along the sidewall thereof. Tunneling oxide layer 30 may be formed along initial charge trap layers 21 of the lateral memory stacks, e.g., along or in contact with the respective radially inner end surfaces of initial charge trap layers 21 facing memory hole 4. Tunneling oxide layer 30 and channel layer 32 may each be conformally deposited, e.g. using a respective ALD process. After depositing tunneling oxide layer 30, tunneling oxide layer 30 may be subjected to an anisotropic etch oriented top-down (opposite the direction of the Z-axis) to remove portions of tunneling oxide layer 30 deposited on horizontally oriented surfaces of structure 1.

Tunneling oxide layer 30 may include SiON. Channel layer 32 may include a semiconductor material such as Si, SiGe, or Ge. While not shown in FIG. 4, channel layer 32 may present an extension outside of the illustrated portion of structure 1, to facilitate connection to peripheral semiconductor devices and circuitry, such as select transistors.

After forming tunneling oxide layer 30 and channel layer 32, memory hole 4 may be filled with plug material 34, such as an inter-layer dielectric (e.g., SiO₂) or other low-k dielectric. Plug material 34 may be deposited by CVD or physical vapor deposition (PVD). Structure 1 may subsequently be planarized (e.g., by chemical mechanical polishing (CMP)) to remove overburden plug material outside memory hole 4, which may result in structure 1 as shown in FIG. 5.

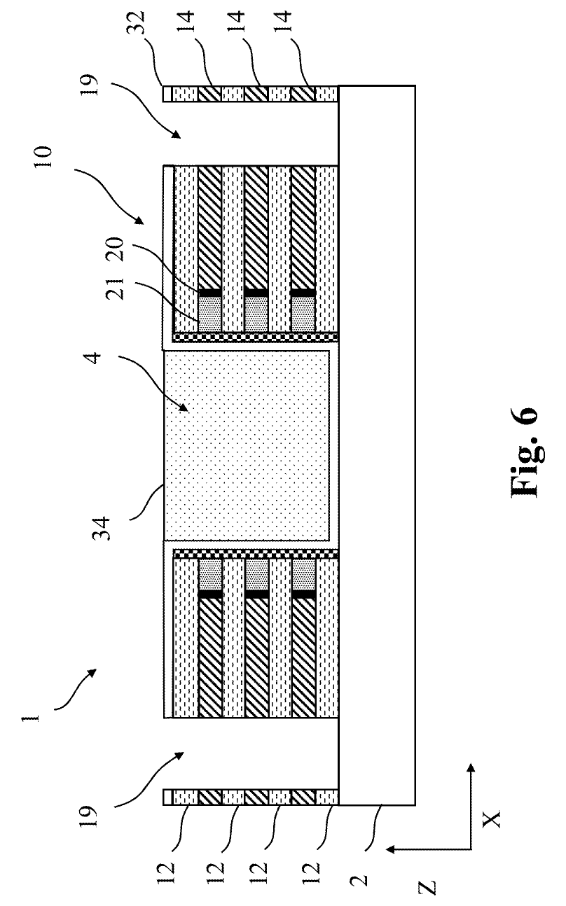

FIG. 6 shows the structure 1 after removing an access trench 19 in the layer stack 10, according to example embodiments. As shown in FIG. 6, access trench 19 may be formed in layer stack 10. Access trench 19 may be formed in layer stack 10 at a location outside of memory hole 4, e.g., laterally/radially spaced apart from memory hole 4. Access trench 19 may extend through each of inter-gate spacer layers 12 and gate layers 14 of layer stack 10. Access trench 19 may expose an end surface of each gate layer of gate layers 14 facing in a radially outward direction with respect to memory hole 4. Access trench 19 may be formed after channel layer 32 and may extend through channel layer 32. Access trench 19 may be patterned in layer stack 10, e.g. by a lithography and etching process.

Access trench 19 may be formed to at least partially surround memory hole 4. Access trench 19 may be formed on opposite sides of memory hole 4, e.g., as a two slit-shaped trench sections, or as a continuously extending trench. Access trench 19 may be formed to circumscribe (e.g., fully circumferentially surround) memory hole 4. Access trench 19 may have a cross-sectional footprint/shape (as seen in a top-down direction) corresponding to memory hole 4. For example, where memory hole 4 is circular, access trench 19 may be annular and substantially concentric with memory hole 4.

While FIG. 6 shows one of access trench 19, a corresponding access trench 19 may be formed for each memory hole 4 of structure 1. In some embodiments, neighboring memory holes may share access trench 19. For instance, a pair of slit-shaped access trench sections may be formed on opposite sides of one or more rows of memory holes.

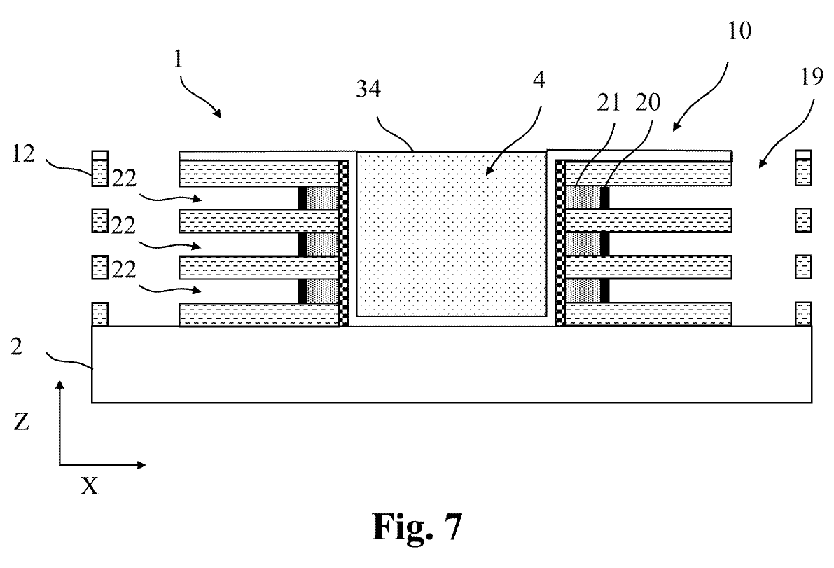

FIG. 7 shows the structure 1 after forming gate cavities 22, according to example embodiments. As shown in FIG. 7, gate cavities 22 may be formed in layer stack 10, between inter-gate spacer layers 12, by laterally etching back gate layers 14 from access trench 19 in a direction towards memory hole 4 (e.g., laterally, in a radially inward direction). The discussion of the lateral etch back of gate layers 14 to form recessed areas 18 may apply to the etching of gate cavities 22. Thus, the etching process may be an isotropic etching process, or any other suitably selective etching process, wet or dry, providing a sufficient lateral etching component for gate layers 14 may be used. For example, gate cavities 22 may be etched using the type of etching process used to form recessed areas 18. Gate layers 14 may further extend radially outward from access trench 19, for instance toward one or more neighboring memory holes.

The etch back may be stopped (e.g., in the radially inward direction) on etch stop layers 20 by separating initial charge trap layers 21 from gate cavities 22. Etch stop layers 20 may be used for the etch-stop detection. A timed etch back may be used where etch stop layers 20 may reduce over-etching into initial charge trap layers 21. The locations of etch stop layers 20 may be determined by the depth of the etch back of gate layers 14 for forming the recessed areas 18. The formation of gate cavities 22 may be insensitive to slight off-centered placements (e.g., non-concentric placements) of access trench 19 relative to memory hole 4, as may occur due to edge placement errors during lithographic patterning of access trench 19.

As depicted in FIG. 7, radially and circumferentially extending gate cavities 22 may be formed at each gate level, wherein each gate cavity of gate cavities 22 may be separated from memory hole 4, which may be filled with plug material 34, by a discrete etch stop layer of etch stop layers 20 and a discrete initial charge trap layer of initial charge trap layers 21. For a circular memory hole 4, gate cavities 22 may be annular.

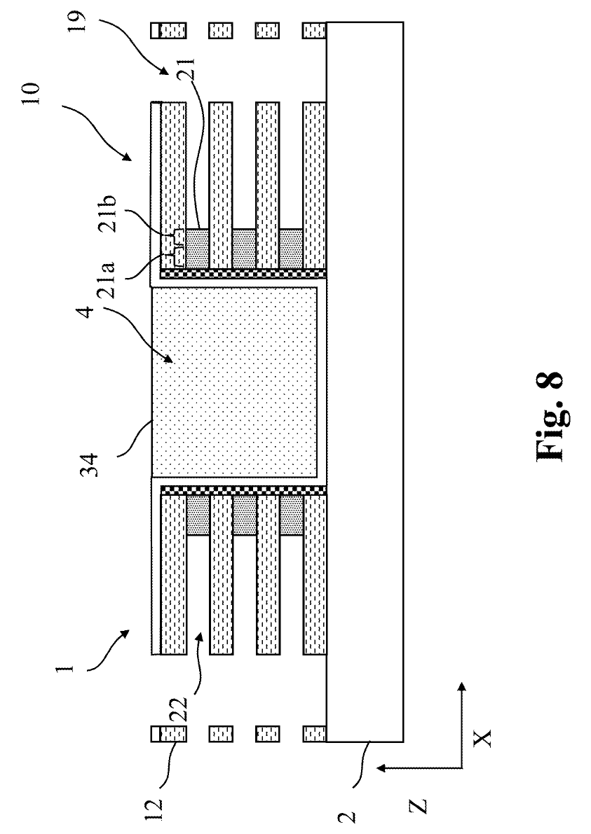

FIG. 8 shows the structure 1 after opening the etch stop layers 20 in the gate cavities, according to example embodiments. As shown in FIG. 8, etch stop layers 20 may be opened (e.g., by a short isotropic etching step) to expose initial charge trap layer 21 in each gate cavity of gate cavities 22, such as a radially outwardly facing end surface of each initial charge trap layer 21. The initial charge trap layers 21 have may be made accessible for the subsequent oxidation process.

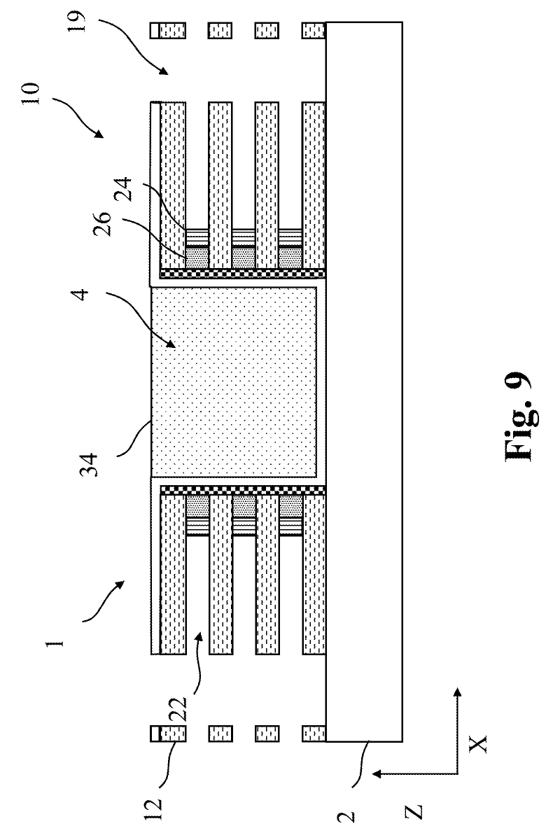

FIG. 9 shows the structure 1 after partially oxidizing the etch stop layers 20 to form blocking oxide layers in each gate cavity, according to example embodiments. As shown in FIG. 9, radially outer portion 21b of initial charge trap layer 21 in each gate cavity 22 may be oxidized to form a discrete blocking oxide layer 24. A radially inner non-oxidized portion 21a of each initial charge trap layer 21 may remain to form a final charge trap layer 26 between blocking oxide layer 24 and memory hole 4. Initial charge trap layers 21 may be exposed to the oxidizing ambient/agent of the oxidation process via gate cavities 22.

A discrete blocking oxide layer 24 may be formed without a separate deposition and etching of a continuous blocking oxide layer. Further, the thickness of blocking oxide layers 24 (e.g., lateral thickness along the X direction) may be precisely controlled via the oxidation depth of initial charge trap layers 21. Assuming an initial thickness of initial charge trap layers 21 in the above-mentioned example range, the oxidation depth, and thus the thickness of blocking oxide layers 20, may for example be in a range of 4-15 nm, and may depend on an initial thickness of initial charge trap layers 21 and a target thickness of final charge trap layers 26.

Where initial charge trap layers 21 are include silicon, such as silicon nitride or Si/metal, blocking oxide layers 24 may include silicon oxide (SiO₂).

The oxidation process may be a thermal oxidation process or a plasma oxidation process. Blocking oxide layers 20 may be formed by a thermal oxide. The oxide may be a low-temperature oxide (LTO) or a high-temperature oxide (HTO).

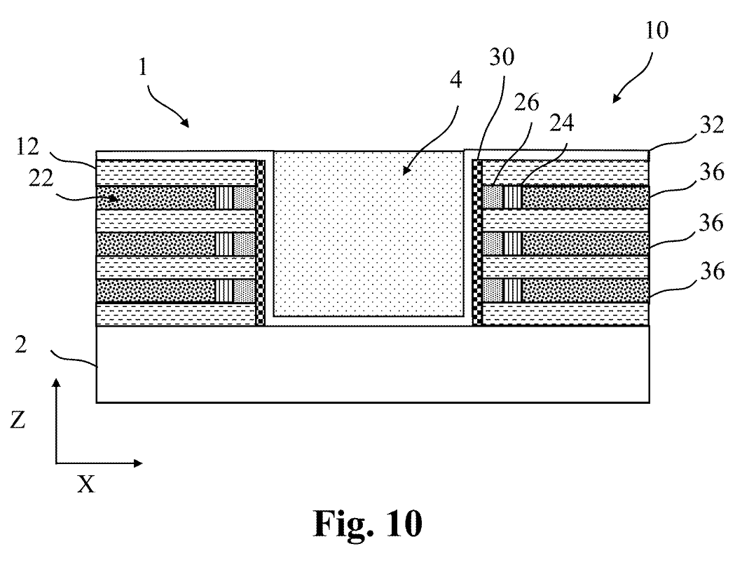

FIG. 10 shows the structure 1 after filling the gate cavities 22 with gate material, according to example embodiments. As shown in FIG. 10, after forming blocking oxide layer 24 and final charge trap layers 26, final (functional) gate layers or stacks 36 may be formed in gate cavities 22 by depositing gate material in gate cavities 22 via access trench 19. This may correspond to a gate layer/gate stack deposition of an RMG process. The gate material deposition may include depositing one or more conductive layers, e.g. metal, such as one or more of TiN and/or W. The deposition of the conductive layer(s) may be preceded by deposition of a (conformal) high-k gate dielectric.

As illustrated in FIG. 10, memory structure 1 may include, for each gate level, discrete blocking oxide layer 24 and discrete charge trap layer 26. These layers may define a lateral memory stack between a respective gate layer/stack 36 and the (shared) tunnel barrier layers 30 and channel layers 32.

The process may further proceed with further steps. For example, structure 1 may be further processed to contact each gate layer of gate layers 3636 to peripheral semiconductor devices and circuitry, such as select transistors and wordline drivers. Contact formation may for example be preceded with patterning gate layers 36 into a staircase structure

Access trench 19 and gate cavities 22 may be formed after forming tunnel barrier layers 30 and/or channel layers 32. The reverse order is also possible. For instance, after forming initial charge trap layers 21, memory hole 4 may be plugged with a temporary plug material. Subsequently, access trench 19 and gate cavities 22 may be formed, blocking oxide layers 24 may be formed by applying the oxidation process, and gate cavities 22 may be filled with gate material 36. Subsequently, the temporary plug material may be removed and the tunnel barrier layers 30 and channel layers 32 may be formed in memory hole 4. Forming access trench 19 and gate cavities 22 after forming tunnel barrier layers 30 and channel layers 32 may result in a more efficient process.

Etch stop layers 20 may be formed prior to forming initial charge trap layers 21. In some embodiments, a corresponding oxidation-based approach for forming blocking oxide layers 24 may be used in a process flow that does not include etch stop layers 20. In some embodiments, following forming of recessed areas 18, discrete initial charge trap layers 21 may be formed in recessed areas 18. Initial charge trap layers 21 may be formed by ASD of charge trap material, seeding from the etched-back end surfaces of gate layers 14 exposed in recessed areas 18 (e.g., after functionalization and/or passivation of gate layers 14 and inter-gate spacer layers 12, respectively). In some embodiments, when forming gate cavities 22 the etch-back of gate layers 14 may be stopped on initial charge trap layers 21. In some embodiments, such an approach may be improve performance where gate layers 14 and charge trap layers 21 are formed of materials providing a sufficient contrast to the etching process used to form gate cavities 22. This approach may be used where the gate material and the charge trap material provide little to no etch contrast provided access trench 19 may be precisely aligned (e.g., concentrically) with memory hole 4 and the etching process may be precisely timed, such that initial charge trap layers 21 may be exposed along the full circumference of memory hole 4 without over-etching in any radial direction.

The person skilled in the art realizes that the present disclosure by no means is limited to the embodiments described above. On the contrary, many modifications and variations are possible within the scope of the appended claims.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. 1. A method comprising:
forming a layer stack over a substrate, the layer stack comprising an alternating sequence of gate layers and inter-gate spacer layers;
forming recessed areas in a sidewall surrounding a memory hole in the layer stack by laterally etching back the gate layers relative to the inter-gate spacer layers from the memory hole to form etched-back gate layers;
for each recessed area, forming an initial charge trap layer;
depositing a tunneling oxide layer in the memory hole;
depositing a channel layer on the tunneling oxide layer;
forming an access trench in the layer stack; forming gate cavities in the layer stack by laterally etching back the gate layers from the access trench in a direction towards the memory hole, wherein the gate cavities expose the initial charge trap layers;
for each of the gate cavities, oxidizing a portion of the initial charge trap layer to form an oxidized portion of the initial charge trap layer and a non-oxidized portion of the initial charge trap layer, wherein the oxidized portion forms a blocking oxide layer, and wherein the non-oxidized portion forms a final charge trap layer between the blocking oxide layer and the memory hole; and
subsequent to forming the blocking oxide layers and the final charge trap layers, forming gate layers in the gate cavities by depositing gate material in the gate cavities via the access trench.

2. The method of claim 1, further comprising:
for each of the recessed areas and prior to forming the initial charge trap layers, forming an etch stop layer on the etched-back gate layers; and
for each of the recessed areas, depositing the initial charge trap layer on the etch stop layer.

3. The method of claim 2, wherein the etch back of the gate layers from the access trench is stopped on the etch stop layer.

4. The method of claim 3, further comprising:
for each of the gate cavities and prior to oxidizing the portion of the initial charge trap layer, opening the etch stop layer to expose the initial charge trap layer.

5. The method of claim 2, wherein the etch stop layer is deposited by a first area-selective deposition process.

6. The method of claim 2, wherein the initial charge trap layer is deposited by a second area-selective deposition process.

7. The method of claim 1, wherein the portion of the initial charge trap layer is oxidized by a thermal oxidation process.

8. The method of claim 1, wherein the portion of the initial charge trap layer is oxidized by a plasma oxidation process.

9. The method of claim 1, wherein the access trench is formed after depositing the tunneling oxide layer.

10. The method of claim 1, wherein the access trench is formed after depositing the channel layer.

11. The method of claim 1, further comprising: filling the memory hole with a plug material prior to forming the access trench.

12. 1. The method of claim 11, wherein the plug material comprises an oxide.

13. The method of claim 2, wherein the etch stop layer comprises a metal oxide.

14. The method of claim 2, wherein the etch stop layer comprises a metal nitride.

15. The method of claim 2, wherein the etch stop layer has a thickness of 2 nanometers or less.

16. The method of claim 1, wherein each of the initial charge trap layers comprises silicon.

17. The method of claim 16, wherein each of the initial charge trap layers comprises silicon nitride.

18. The method of claim 1, wherein each of the inter-gate spacer layers have a thickness between 5 nanometers and 25 nanometers, and wherein each of the gate layers have a thickness between 5 nanometers and 25 nanometers.

19. The method of claim 18, wherein each pair of the inter-gate spacer layer and the gate layer have a combined thickness of 45 nanometers or less.

20. The method of claim 1, wherein the memory hole is circular, wherein each of the gate cavities is annular, wherein each of the recessed areas is annular, and wherein the access trench is annular.
